(19) United States
(12) Patent Application Publication
(10) Pub. No.: US 2017/0087602 A1
(43) Pub. Date: Mar. 30, 2017

(54) METHOD AND APPARATUS FOR TREATING SUBSTRATE

(71) Applicant: SEMES CO., LTD., Chungcheongnam-do (KR)

(72) Inventors: Janghee Lee, Gyeonggi-do (KR); Sunrae Kim, Gyeonggi-do (KR); Jinwoo Nam, Chungcheongbuk-do (KR); Young Hak Park, Chungcheongnam-do (KR); Jin Woo Choi, Gyeonggi-do (KR)

(21) Appl. No.: 15/278,569

(22) Filed: Sep. 28, 2016

(30) Foreign Application Priority Data
Sep. 30, 2015 (KR) 10-2015-0138022

(51) Int. Cl. B08B 7/00; B08B 9/08; H01L 21/3065

(52) U.S. Cl. CPC B08B 7/0035; H01L 21/3065; B08B 9/08

(57) ABSTRACT

The present disclosure relates to a method for treating a substrate. A method for treating a substrate includes a chamber cleaning step. In the chamber cleaning step a treatment space is cleaned by supplying a cleaning fluid. The cleaning fluid is generated by chemical reaction of a first gas and a second gas by applying plasma while supplying the first gas and the second gas which is different from the first gas into the inside of the process chamber.

### CROSS-REFERENCE TO RELATED APPLICATIONS

A claim for priority under 35 U.S.C. §119 is made to Korean Patent Application No. 10-2015-0138022 filed on Sep. 30, 2015, in the Korean Intellectual Property Office, the entire contents of which are hereby incorporated by reference.

### BACKGROUND OF THE INVENTION

The present invention disclosed herein relates to an apparatus for treating a substrate and a method for treating a substrate, and more particularly relates to a method and an apparatus for treating a substrate by using plasma.

Plasma is generated by very high temperature, strong electric field, or RF electromagnetic fields, and refers to ionized gas state composed of ion, electron, and/or radical etc. In a process of manufacturing a semiconductor device, different processes are performed by using plasma. For example, an etching process may be performed by colliding ion particles contained in the plasma with a substrate.

In case of a substrate treating apparatus that generates plasma by using a microwave to treat a substrate, members made of a material containing quartz SiO₂ and exposed to a treating space where a substrate treating process is performed are provided in a process chamber, for example a dielectric plate is provided to deliver microwave to the process chamber from an antenna. These members get replaced by a certain period as they get etched and damaged by plasma during process. After members including quartz SiO₂ material get replaced, a cleaning process is carried out to clean inside of the process chamber by using cleaning solution to remove the contaminants and then chamber cleaning process called plasma SEASONING is performed for the inside of the process chamber for a long time to remove the contaminants generated by the cleaning process and remaining contaminants.

Generally during the plasma seasoning, F₂ generated from a plasma reaction by supplying NF3 to the inside of process chamber cleans the inside of the process chamber. In this case, F₂ not only cleans the inside of the process chamber but also etches and damages the member provided as material including quartz due to its strong reactivity, thereby generating contaminants.

### SUMMARY OF THE INVENTION

Some example embodiments of the inventive concept provide a method and an apparatus for treating a substrate which could minimize the damage of member that includes quartz material in an apparatus for treating substrate using plasma.

Some example embodiments of the inventive concept provide a method and an apparatus for treating a substrate which could minimize generation of contaminants.

Some example embodiments of the inventive concept provide a method and an apparatus for treating a substrate which could increase the efficiency of cleaning inside of process chamber.

The objects of the present invention are not limited to the above mentioned descriptions. Other objects of the present invention and implementation methods thereof will be clarified through following embodiments described with reference to the accompanying drawings and following detailed descriptions.

According to some example embodiments, a method for treating a substrate comprises: a chamber cleaning step for treating space of a process chamber, the process chamber providing the treating space inside thereof for treating a substrate by using a plasma; and a process treating step for treating a substrate. In the chamber cleaning, a cleaning fluid is supplied in the treating space to clean the treating space, and the cleaning fluid is generated by reacting chemically a first gas and a second gas that is different from the first gas by applying a plasma while providing the first gas and the second gas to the inside of the process chamber and.

In some embodiments, the first gas is a gas including NF₃, and the second gas is provided as a gas including H₂.

In some embodiments, the cleaning fluid is provided as a fluid including HF.

In some embodiments, in the chamber cleaning step, a third gas including inert gas is further provided in the treatment space.

In some embodiments, the inert gas may be Ar gas.

In some embodiments, the chamber cleaning step and process treating step may be performed at the same temperature.

In some embodiments, a ratio between supply mass of the first gas and supply mass of the second gas may be any one of 1:1, 1:2, and 1:3.

In some embodiments, a ratio between supply mass of the second gas and supply mass of the first gas may be 1:1 to 3:1.

In the treatment space, a member provided as a material including quartz SiO₂ is provided to be exposed.

In some embodiments, the member may be provided as a dielectric plate that delivers a microwave from an antenna to inside of the process chamber or may be provided as a liner installed on an internal wall of the process chamber.

In some embodiments, before the chamber cleaning step, the method may further comprise a pre-cleaning step for cleaning the treatment space by providing a cleaning solution in the treating space.

According to some example embodiments, an apparatus for treating a substrate comprises: a process chamber having a treatment space inside thereof; a substrate supporting unit configured to support a substrate inside of the process chamber;: an antenna having a plurality of slots and arranged over the substrate supporting unit; a microwave applying unit configured to apply a microwave to the antenna; a gas supplying unit configured to supply a gas in the treatment space; a member that is provided as a material including quartz and is provided to be exposed in the treating space; and a controller configured to control the microwave applying unit and the gas supplying unit, wherein the controller controls the gas supplying unit and the microwave applying unit as to generate a cleaning fluid by applying a microwave while supplying a first gas and a second gas that is different from the first gas in the treat space when cleaning the treatment space.

In some embodiments, the member may be a dielectric plate which delivers a microwave from the antenna to inside of the process chamber or may be a liner installed on an internal wall of process chamber.

In some embodiments, the first gas is a gas including NF₃, and the second gas is provided as a gas including H₂.

In some embodiments, the cleaning fluid is provided as a fluid including HF.

In some embodiments, the controller is further configured to control the gas supply unit as to supply an inert gas together with the first gas and the second gas when cleaning the treatment space.

According to example embodiments of the inventive concept, the above-mentioned method and apparatus for treating a substrate could minimize the damage of a member including quartz material and provided in the apparatus for treating a substrate using plasma.

According to further example embodiments of the inventive concept, the above-mentioned method and apparatus for treating a substrate could minimize generation of contaminant material.

According to further example embodiments of the inventive concept, the above-mentioned method and apparatus for treating a substrate could increase the efficiency of cleaning inside of the process chamber.

### BRIEF DESCRIPTION OF THE DRAWINGS

FIG. 1 shows an apparatus for treating a substrate in accordance with an embodiment of the present invention.

FIG. 2 is a plan view of bottom side of an antenna of FIG. 1.

FIG. 3 is a flow chart of a method for treating a substrate in accordance with an embodiment of the present invention.

FIG. 4 shows an apparatus for treating a substrate in accordance with another embodiment of the present invention.

### DETAILED DESCRIPTION

Hereinafter, example embodiments of the inventive concept will now be described more fully with reference to the accompanying drawings, in which example embodiments are shown. Example embodiments of inventive concept may, however, be embodied in many different forms and should not be construed as being limited to the embodiments set forth herein; rather, these embodiments are provided so that this disclosure will be through and complete, and will fully convey the concept of example embodiments to those of ordinary skill in the art. In drawings, the shapes and features of components are exaggerated for clarity.

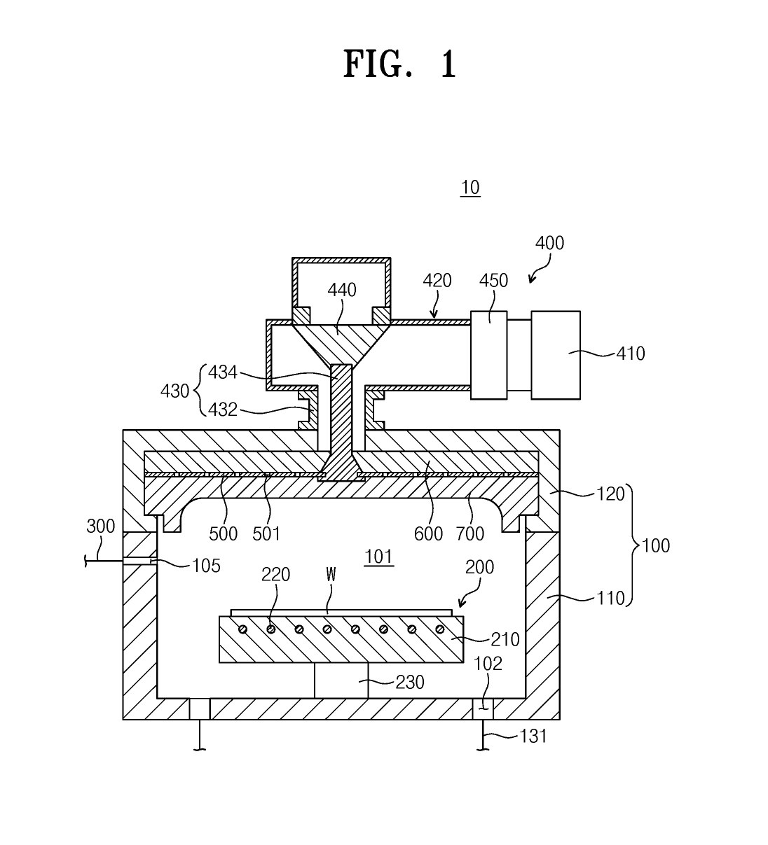

FIG. 1 shows an apparatus for treating a substrate in accordance with an embodiment of the present invention. Referring to FIG. 1, the apparatus for treating a substrate 10 performs a plasma process to a substrate W. The apparatus for treating a substrate 10 includes a process chamber 100, a substrate supporting unit 200, a gas supplying unit 300, a microwave applying unit 400, an antenna 500, a slow-wave plate 600, a dielectric plate 700, and a controller (not described).

In the process chamber 100, a treatment space 101 is performed inside, and the treatment space 101 is provided as a space for treating a substrate W. For example, the treatment space 101 is provided as a space for treating a substrate by using plasma. The process chamber 100 includes a body 110 and a cover 120. The body 110 has an open upper side and a space is formed inside. The cover 120 is placed on a top of the body 110 and seals an open upper side of the body 110. The inner side wall of the cover 120 has a step profile at the lower portion facing the substrate such that a width (e.g., a diameter) of the upper portion of the space defined by the cover 120 is greater than a width (e.g., a diameter) of the lower portion of the space defined by the cover 120.

In one side wall of the process chamber 100, an opening (not shown) may be formed. The opening is provided as a passage for a substrate W to enter into and to go out inside of the process chamber 100. The opening is closed by a door (not shown).

In a bottom side (bottom wall) of the process chamber 100, an exhaust hole 102 is formed. The exhaust hole 102 is connected to an exhaust line 131. Inside of the process chamber 100 may be maintained as a lower pressure than atmospheric pressure by an exhaust through the exhaust line 131. Also, a by-product generated from a process and gas that stays inside of the process chamber 100 may be discharged outside through the exhaust line 131.

The substrate supporting unit 200 is placed inside of the process chamber 100, and supports substrate W. The substrate supporting unit 200 includes a supporting plate 210, a lift pin (not shown), a heater 220 and a supporting shaft 230.

The supporting plate 210 has a certain thickness, and is provided as a circular plate that has a greater radius than the substrate W. On a top surface of the supporting plate 210, a substrate W is placed. According to an embodiment, in the supporting plate 210 a component that fixes the substrate W is not provided, and the substrate W is provided for a process as placed on the top surface of the supporting plate 210. Unlike this, the supporting plate 210 may be provided as an electrostatic chuck that fixes the substrate W by using an electrostatic energy, or may be provided as a chuck that fixes the substrate W by a mechanical clamping means. During plasma seasoning in a chamber cleaning step S20 which will be described below, a dummy substrate may be placed on the supporting plate 210 to protect the exposed side of the supporting plate 210.

The lift pin is provided as a plurality of lift pins and each lift pin is placed on respective pin hole (not shown) which is formed in the supporting plate 210. The lift pins load the substrate W on the supporting plate 210 or unloads the substrate that is placed on the supporting plate 210 while moving up and down along respective pin holes.

The heater 220 is provided inside the supporting plate 210. The heater 220 may be provided as a coil of spiral form, and may be embedded and spaced apart from each turn thereof inside the supporting plate 210 by even distance. The heater 220 is connected to an external power (not shown), and generates heat by resisting current by the external power. The generated heat is delivered to the substrate W through the supporting plate 210, and heats the substrate W to a predetermined temperature.

The supporting shaft 230 is provided at the bottom of the supporting plate 210, and supports the supporting plate 210.

The gas supplying unit 300 supplies a process gas to inside of the process chamber 100. The gas supplying unit 300 may supply the process gas to inside of the process chamber 100 through a gas supplying hole 105 which is formed on a side wall of the process chamber 100. Also, the gas supplying unit 300 may supply a first gas, a second gas, and a third gas, which are supplied in the treatment space 101 during a chamber cleaning step S20 explained later, through the gas supplying hole 105. However, the first gas, the second gas and the third gas may be provided by a separate supplying unit (not shown) that is different form the gas supplying unit 300.

The microwave applying unit 400 applies microwave to the antenna 500. The microwave applying unit 400 includes a microwave generator 410, a first waveguide 420, a second waveguide 430, a phase converter 440, and a matching network 450.

The microwave generator 410 generates microwave.

The first waveguide 420 is connected to the microwave generator 410, and has a passage inside thereof. A microwave that is generated from the microwave generator 410 is delivered to the phase converter 410 through the first waveguide 420.

The second waveguide 430 includes an outer conductor 432 and an inner conductor 434.

The outer conductor 432 is vertically connected to the end of the first waveguide 420, extending downward, and has a passage inside thereof. An upper part of the outer conductor 432 is connected to a bottom part of the first waveguide 420, and a bottom part of the outer conductor 432 is connected to an upper part of the cover 120.

The inner conductor 434 is placed inside the outer conductor 432. The inner conductor 434 is provided as a rod of cylinder form, and is arranged such that the lengthwise direction thereof is parallel with up and down direction. The upper part of the inner conductor 434 is fixedly inserted into the bottom part of the phase converter 440. The inner conductor 434 is extended downwardly into inside of the process chamber 100. The bottom part of the inner conductor 434 is fixedly connected to a center of the antenna 500. The inner conductor 434 is arranged vertically on the upper surface of the antenna 500. The inner conductor 434 may be provided as a rod of copper sequentially coated with a first plating film and a second plating film. According to an embodiment, the first plating film may be provided as Ni material, and the second plating film may be provided as Au material. Microwave is delivered to the antenna 500 through mainly the first plating film.

A microwave whose phase is converted by the phase converter 440 is delivered to the antenna 500 through the second waveguide 430.

The phase converter 440 is provided at the location where the first waveguide 420 and the second waveguide connect, and converts the phase of a microwave. The phase converter 110 may be provided as a cone shape where a bottom thereof is sharp. The phase converter 440 propagates a microwave which has been sent from the first waveguide 420 to the second waveguide 430 as a mode of the microwave is converted. The phase converter 440 may convert microwave from TE mode to TEM mode.

The matching network 450 is provided at the first waveguide 420. The matching network 450 matches microwave which propagates through the first waveguide 420 with a predetermined frequency.

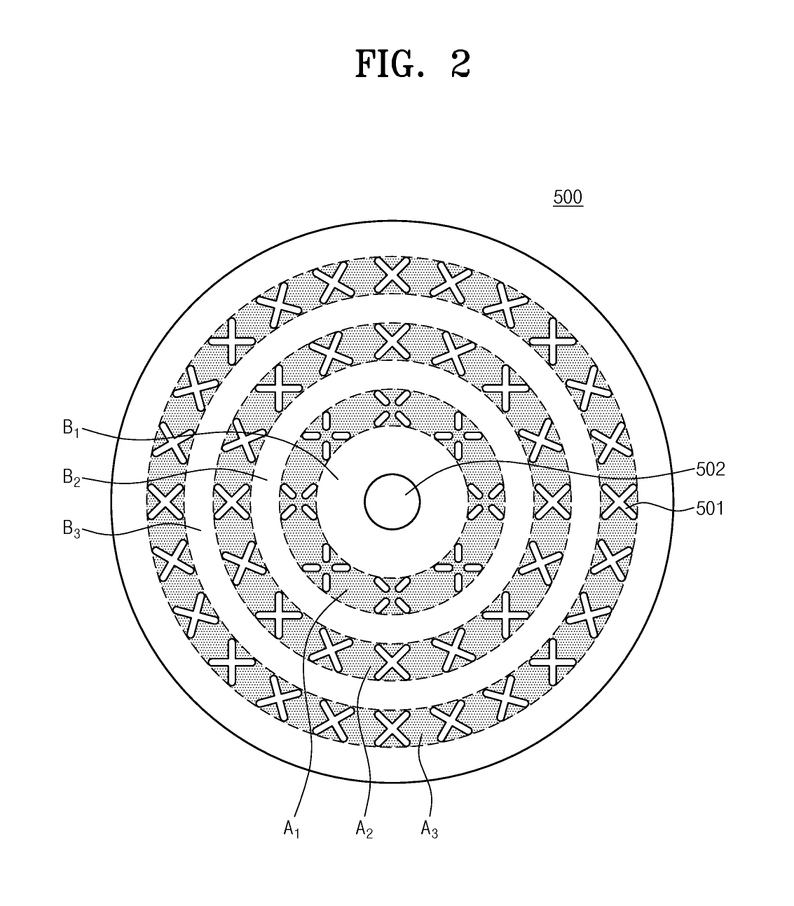

FIG. 2 is a plan view of a bottom side of the antenna of FIG. 1. Referring to FIGS. 1 and 2, the antenna is provided as a plate form. For example, the antenna 500 may be provided as a circular plate having a thin thickness. The antenna 500 is arranged over the substrate supporting unit 200, facing the supporting plate 210. In the antenna 500, a plurality of slots 501 are provided. The slot 501 may be provided as ‘x’ shape. However, shape and arrangement of the slots may be changed variously. The slots 501 are arranged as a plurality of rings. Hereinafter, first areas A1, A2, and A3 refer to an antenna area where the slots 501 are formed, and second areas B1, B2, and B3 refer to an antenna area where slots 501 are not formed. Each of the first areas A1, A2, and A3 and the second areas B1, B2, and B3 has ring shape. The first areas A1, A2, and A3have different radius with each other. The first areas A1, A2, and A3 have the same center, and are placed separately to the radius direction of the antenna 500. The second areas B1, B2, and B3 have different radius with each other. The second areas B1, B2, and B3have the same center, and are placed separately to the radius direction of the antenna 500. Each of the first areas A1, A2, and A3 is placed between the second area B1, B2, and B3, respectively. In the center part of the antenna 500, a hole 502 is provided. The inner conductor 434 passes through the hole 502 and reaches and connects with the antenna 500. The microwave is delivered to the dielectric plate 700 by penetrating the slots 501.

Again, referring to the FIG. 1, the slow-wave plate 600 is placed over the antenna 500, and is provided as a circular plate having a predetermined thickness. The slow-wave plate 600 may have a radius that corresponds to inner side of the cover 120. A microwave which has been propagated to a vertical direction through the inner conductor 434 is then propagated to a radius direction in the slow-wave plate 600. A microwave that is propagated at the slow-wave plate 600 is resonated and frequency thereof is compressed. Also a microwave that is reflected from the dielectric plate 700 is sent back to the dielectric plate 700 by re-reflecting. The slow-wave plate 600 is provided as dielectric material.

The dielectric plate 700 is placed below the antenna 500, and is provided as a circular plate having a predetermined thickness. A bottom side of the dielectric plate 700 is provided as a concave surface 700. The bottom surface the dielectric plate 700 may be placed at the same height with a lower end of the cover 120. The dielectric plate 700 has an outer sidewall having a step profile at the lower portion facing the substrate such that the upper outer sidewall has a greater diameter than the lower outer sidewall. The dielectric plate 700 is placed on the cover 120 such that the step portion of the dielectric plate 700 is placed on the step portion of the cover 120. Herein, the outer sidewall of the lower portion of the dielectric plate 700 has a lesser than the inner sidewall of the lower portion of the cover 200, such that the lower portion of the dielectric plate 700 is spaced apart from the lower portion of the cover 200. According to an embodiment, the slow-wave plate 600, the antenna 500, and the dielectric plate 700 may be adhered to each other. A microwave is eradicated from the antenna 500 to the inner side of the process chamber 100 passing through the dielectric plate 700. A process gas that is provided at the process chamber 100 is excited as plasma state by an electric field of an eradiated microwave. The dielectric plate 700 is provided as a dielectric material. For example, the dielectric plate 700 may be provided as a material including quartz SiO₂. Therefore, the dielectric plate 700 may be etched and damaged by a reaction with plasma during a substrate treating process by using plasma or chamber cleaning process like SEASONING by using plasma. Therefore, this may generate contaminant, and the dielectric plate 700 may be replaced by a certain period.

A controller controls the microwave applying unit and the gas supplying member. For example, when cleaning the treatment space 101 the controller controls the gas supplying unit 300 and the microwave applying unit 400 to generate cleaning fluid by applying microwave while providing the first gas and the second gas to the treatment space 101. Also, when cleaning the treatment space 101 the controller controls the gas supplying unit 300 to further provide an inert gas together with the first gas and the second gas.

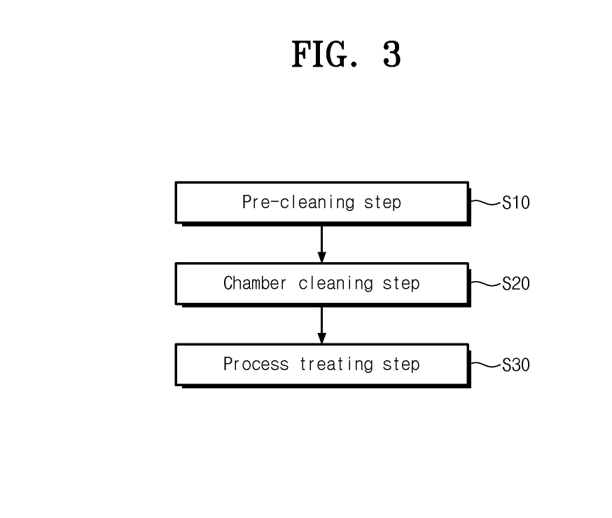

Hereinafter, a method for treating substrate by using a substrate treating apparatus of the FIG. 1 will be described. FIG. 3 is a flow chart of a method for treating substrate in accordance with an embodiment of the present invention. Referring to the FIGS. 1 and 3, a method for treating substrate in accordance with an embodiment of the present invention includes a pre-cleaning step S10, a chamber cleaning step S20, and a process treating step S30. The pre-cleaning step S10, the chamber cleaning step S20, and the process treating step S30 is performed sequentially.

In the pre-cleaning step S10 it cleans the treatment space 101 by supplying cleaning fluid to the treatment space 101. The pre-cleaning step S10 is performed before the chamber cleaning step S20. Before the pre-cleaning step S10 replacement or maintenance of a member that is provided as a material including quartz SiO₂and exposed to the treatment space 101 may be performed. The pre-cleaning step S10 and the chamber cleaning step S20 may be performed to remove contaminant generated from the replacement or maintenance of a member that is provided as a material including quartz SiO₂. The member that is provided as material including quartz SiO₂ may be the dielectric plate 700. When the cover 120 is removed and the treatment space 100 is exposed, the cleaning fluid may be supplied through upper part of the treatment space 101. Unlike this, it may be provided to the treatment space 101 with many different ways. For example, the cleaning fluid may be supplied passing through the internal wall of the process chamber 100 by a supplying unit (not shown).

In the chamber cleaning step S20 it cleans the treatment space 101 by supplying cleaning fluid into the treatment space 101. The cleaning fluid may be provided as a fluid including HF. The cleaning fluid is generated by a chemical reaction of the first gas and the second gas. For example, applying plasma while providing the first gas and the second gas into the treatment space 101 will cause the chemical reaction between the first gas and the second gas, thereby generating the cleaning fluid. The first gas and the second gas are provided by the gas supplying unit 300. However, the first gas and the second gas may be supplied by a separate supplying unit that is different from the gas supplying unit 300. The first gas and the second gas are different gases from each other. For example, the first gas is a gas including NF₃, and the second gas is provided as a gas including H₂. In this case, NF₃ and H₂ reacts each other by plasma and generate N₂ and HF. H₂ has a strong reactivity with NH₃and thereby increasing cleaning efficiency by increasing generation efficiency of HF. Therefore, time of cleaning the chamber may be shortened, and the number of dummy substrate which is placed on the substrate supporting unit 200 for preventing plasma during the cleaning step from damaging the substrate supporting unit 200 will be decreased. Also, generally HF has a lower reactivity to the quartz material than the F₂ which is usually used in cleaning fluid, thereby minimizing a damage of a member that includes quartz material in the chamber cleaning step S20. Therefore, the generation of contaminant caused by the damage of the member including quartz material can be minimized. Also, the treatment space 101 can be uniformly cleaned by generating and providing HF, which exists as liquid state at the room temperature, through reacting the first gas and the second gas in the treatment space 101, as compared to the conventional method of directly supplying liquid state HF. A ratio of a supply mass of the second gas to the supply mass of the first gas may be provided differently depending on an object apparatus of cleaning or during process. For example, the ratio of a supply mass of the second gas and the supply mass of the first gas may be any one of 1:1, 2:1, or 3:1.

In the chamber cleaning step S20, the third gas may further be provided together with the first gas and the second gas in the treatment space 101. The third gas is provided as an inert gas. For example, the third gas may be provided as Ar gas. The third gas may be excited as plasma by a microwave and supply energy to the reaction of the first gas and second gas to generate a cleaning fluid. The third gas may be supplied to a treatment space 101 by the gas supplying unit 300. However, the third gas may be supplied to the treatment space 101 by separate supplying unit (not shown) different from the gas supplying unit 300.

In the process treating step S30, a process to a substrate W is performed. For example, a substrate W to be treated is placed on the substrate supplying unit 200, and plasma is generated as process gas is provided by the gas supplying unit 300 and as microwave is applied by the microwave applying unit 400. Therefore a process to a substrate W is performed by the process gas in plasma state.

The chamber cleaning step S20 and a process treating step S30 may be performed at the same temperature. For example, the chamber cleaning step S20 and the process treating step S30 may be performed at a temperature where an inert gas could be excited as plasma to supply reaction energy to a process gas or to the first gas and the second gas.

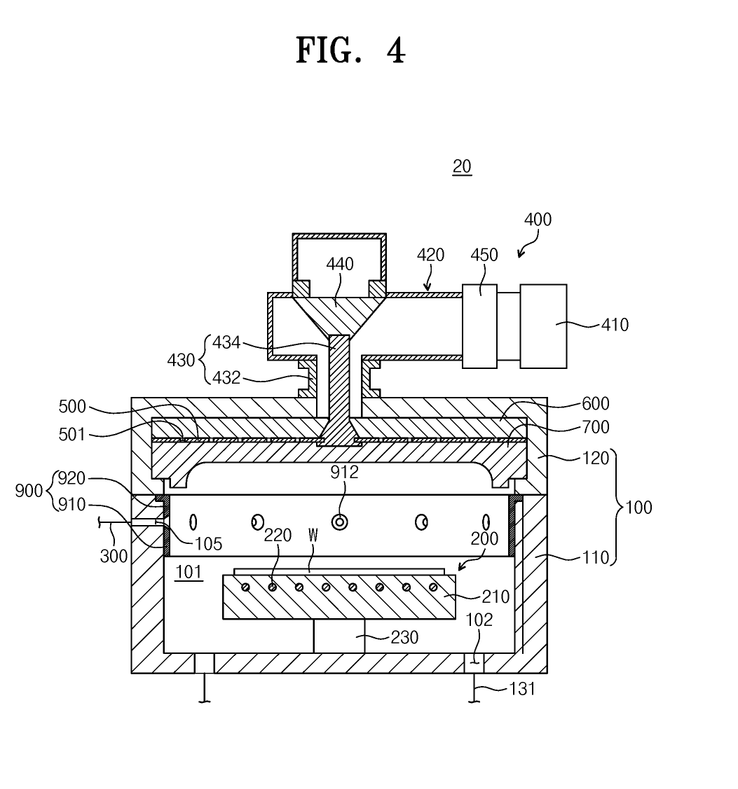

FIG. 4 shows an apparatus for treating substrate in accordance with another embodiment of the present invention. Referring to FIG. 4, in the substrate treating apparatus20 to which a method for treating substrate of the present invention is applied, a member including quartz may be provided as a liner 900. The liner 900 is installed at the internal wall of the process chamber 100. The liner 900 prevents damaging internal wall of the process chamber 100 by plasma. The liner 900 includes a body 910 and a flange 920.

The body 910 has a ring shape facing inner wall of the process chamber 100. In the body 910, a penetration hole 912 is formed to correspond to the gas supplying hole 105. A process gas that is sprayed from the gas supplying hole 105 is flowed into the process chamber 100 through the penetration hole 912.

The flange 920 may be provided to be extendable from an outer wall of the body 910 to inside of the wall of the process chamber 100. The flange 920 is provided as a ring shape that encase circumference of the body 910. The flange 920 may be provided at the top of the body 910.

Besides, a component, a function and a structure of the substrate treating apparatus 20 are similar to the substrate treating apparatus 10 of the FIG. 1.

FIGS. 1 and 4 shows a liner and a dielectric plate that are provided as a member including quartz, but a method for treating substrate of the present invention may be applied to any substrate treating apparatus having a member provided as a material including quartz.

The controller controls the microwave applying unit 400 and the gas supplying unit 300 of each substrate treating apparatus 10, 20 such that above-mentioned the method for treating a substrate can be performed.

What is claimed is:

1. A method for treating a substrate comprising:
cleaning a treatment space of a process chamber, the process chamber providing the treatment space inside thereof for treating a substrate by plasma; and
treating substrate,
wherein the cleaning cleans the treatment space by providing a cleaning fluid,
wherein the cleaning fluid is generated by reacting chemically a first gas and a second gas by applying plasma while providing the first gas and the second gas that is different from the first gas with each other to the inside of the process chamber.

2. The method of claim 1, wherein the first gas is a gas including NF₃, and the second gas is provided as a gas including H₂.

3. The method of claim 1, wherein the cleaning fluid is provided as a fluid including HF.

4. The method of claim 2, wherein in the cleaning a third gas including an inert gas is further provided in the treatment space.

5. The method of claim 4, wherein the inert gas is Ar gas.

6. The method of claim 5, wherein the cleaning and the treating are performed at the same temperature.

7. The method of claim 2, wherein a ratio between a supply mass of the first gas and a supply mass of the second gas is any one of 1:1, 1:2, and 1:3.

8. The method of claim 2, wherein a ratio between a supply mass of the second gas to the supply mass of the first gas is 1:1˜3:1.

9. The method of claim 1, wherein in the treatment space a member comprising a material including quartz SiO₂ configured to be exposed.

10. The method of claim 9, wherein the member is a dielectric plate that delivers microwaves from an antenna to an inside of the process chamber.

11. The method of claim 9, wherein the member is a liner that is installed on the internal wall of the process chamber.

12. The method of claim 1, further comprising pre-cleaning before the cleaning step, wherein the pre-cleaning cleans the treatment space by providing a cleaning fluid to the treatment space.

13. An apparatus for treating a substrate comprising:
a process chamber having a treatment space inside thereof;
a substrate supporting unit for supporting a substrate inside of the process chamber;
an antenna having a plurality of slots and disposed over the substrate supporting unit;
a microwave applying unit for applying a microwave to the antenna;
a gas supplying unit for supplying a gas in the treatment space;
a member comprising a material including quartz and configured to be exposed in the treatment space; and
a controller for controlling the gas supplying unit and the microwave applying unit,
wherein the controller controls the gas supplying unit and the microwave applying unit as to generate a cleaning fluid by applying microwaves while supplying a first gas and a second gas that is different from the first gas into the treatment space when cleaning the treatment space.

14. The substrate treating apparatus of claim 13, wherein the member is a dielectric plate which delivers microwaves from the antenna to an inside of the process chamber.

15. The substrate treating apparatus of claim 13, wherein the member is a liner installed in an internal wall of process chamber.

16. The substrate treating apparatus of claim 13, wherein the first gas is a gas including NF₃, and the second gas is a gas including H₂.

17. The substrate treating apparatus of claim 13, wherein the cleaning fluid includes HF.

18. The substrate treating apparatus of claim 16, wherein the controller controls the gas supplying unit to further provide an inert gas together with the first gas and the second gas when cleaning the treatment space.
